(19) United States
(12) Patent Application Publication
(10) Pub. No.: US 2025/0125784 A1
(43) Pub. Date: Apr. 17, 2025

(54) SURFACE ACOUSTIC WAVE DEVICE AND FABRICATING METHOD OF THE SAME

(71) Applicant: WISOL CO., LTD., Osan-si (KR)

(72) Inventors: Hun Yong LEE, Osan-si (KR); Tae Hyun KIM, Osan-si (KR); Yoshikazu KIHARA, Osan-si (KR)

(21) Appl. No.: 18/892,416

(22) Filed: Sep. 22, 2024

(30) Foreign Application Priority Data
Oct. 13, 2023 (KR) 10- 2023-0136436

(51) Int. Cl. H03H 9/02; H03H 3/08; H03H 9/25

(52) U.S. Cl. CPC H03H 9/02574; H03H 3/08; H03H 9/25

(57) ABSTRACT

Provided is a surface acoustic wave device and a method of manufacturing the same. The surface acoustic wave device includes: a semiconductor support substrate; a modified substrate surface layer formed on a surface of the support substrate; a low acoustic velocity layer formed on the modified substrate surface layer; a piezoelectric layer formed on the low acoustic velocity layer; and a plurality of IDT electrodes disposed on the piezoelectric layer, wherein surface roughness of one side of the modified substrate surface layer is 0.2nm or lower.

### BACKGROUND OF THE INVENTION

### Field of the Invention

The present invention relates to a surface acoustic wave device and a method of manufacturing the same, and more particularly, to a surface acoustic wave device and a method of manufacturing the same, which can prevent increase in high-frequency loss and deterioration of Q, and simplify the manufacturing process by forming a modified substrate surface layer on the surface of a support substrate.

### Background of the Related Art

A structure of sequentially laminating a high acoustic velocity layer 110, a low acoustic velocity layer 120, and a piezoelectric layer 130 on a support substrate 100 as shown in FIG. 1 is known as a technique for improving the Q of a surface acoustic wave (SAW) resonator. Alternatively, when a high acoustic velocity support substrate 101 is used as shown in FIG. 3, the high acoustic velocity layer is acoustically unnecessary and may be omitted.

When a silicon substrate, which is a semiconductor, is used as a high acoustic velocity support substrate, there is a problem in that as a parasitic conducting layer is generated at the silicon substrate interface due to interactions between carriers contained in SiO₂, which is an oxide, and the silicon substrate, which is a semiconductor, high-frequency loss increases, and Qmax of the SAW resonator is significantly deteriorated. The high-frequency loss is not resolved although the silicon substrate is configured to have a high resistivity of 4 to 10 kΩ·cm.

To suppress the carriers passing through the silicon interface, amorphous silicon (a-Si) or polysilicon (polySi) may be laminated on the silicon substrate as shown in FIG. 2, or a trap-rich layer 102 may be formed by ion implantation. The trap-rich layer 102 may prevent decrease in the resistance of the silicon interface by lowering mobility of the carriers. The amorphous silicon or polysilicon may also function as a high acoustic velocity layer since the surface acoustic wave velocity is higher than that of LiTaO₃ or LiNbO₃ used as a piezoelectric layer.

In order to sufficiently suppress the high-frequency loss, the amorphous silicon or polysilicon layer needs to be deposited at a thickness of about 400 to 1000 nm using a Low-Pressure Chemical Vapor Deposition (LPCVD) device, a Plasma Enhanced Chemical Vapor Deposition (PECVD) device, or a sputtering device. The LPCVD device is suitable for depositing the trap-rich layer since it has low equipment cost and high productivity, compared to the PECVD or sputtering device.

In the case where ions are implanted on the silicon surface, an amorphous layer may be formed to a depth of about 50 nm when argon (Ar) is used as the ion. The ion implantation device has a problem in that investment in high-cost facilities is required and manufacturing cost is increased as the productivity is lowered compared to the LPCVD device.

### SUMMARY OF THE INVENTION

An object of the present invention to solve the technical problem is to provide a surface acoustic wave device having reduced manufacturing cost compared to a four-layer laminating structure, while reducing high-frequency loss and minimizing deterioration of Q performance.

The technical problems of the present invention are not limited to the technical problems mentioned above, and unmentioned other technical problems will be clearly understood by those skilled in the art from the following description.

To solve the technical problem, a surface acoustic wave device according to some embodiments of the present invention comprises: a support substrate; a modified substrate surface layer formed on the surface of the support substrate; a low acoustic velocity layer formed on one side of the modified substrate surface layer; a piezoelectric layer formed on the low acoustic velocity layer; and a plurality of IDT electrodes disposed on the piezoelectric layer, wherein surface roughness of one side of the modified substrate surface layer may be 0.2 nm or lower.

In some embodiments of the present invention, the modified substrate surface layer may include an amorphous layer of a material constituting the support substrate, and the surface roughness may be roughness of the boundary surface between the support substrate and the low acoustic velocity layer.

In some embodiments of the present invention, the modified substrate surface layer may contain any one among argon, helium, krypton, and xenon.

In some embodiments of the present invention, the thickness of the modified substrate surface layer may be 10 nm or lower.

In some embodiments of the present invention, when the wavelength of the surface elastic wave determined by the interval of disposing the plurality of IDT electrodes is λ, the thickness of the piezoelectric layer and the low acoustic velocity layer may be 1λ or less.

In some embodiments of the present invention, the support substrate may contain at least any one material among a silicon substrate, a silicon carbide, and a gallium nitride.

To solve the technical problem, a method of manufacturing a surface acoustic wave device according to some embodiments of the present invention comprises the steps of: forming a modified substrate surface layer by performing plasma surface treatment on the surface of a support substrate; forming a low acoustic velocity layer on a piezoelectric layer; and bonding the substrate surface layer and the surface of the low acoustic velocity layer.

In some embodiments of the present invention, the plasma surface treatment process may include plasma treatment using any one material among argon, helium, krypton, and xenon, and the modified substrate surface layer may partially contain any one material among the argon, helium, krypton, and xenon used in the plasma treatment.

In some embodiments of the present invention, the method of manufacturing a surface acoustic wave device may further comprise the step of forming a plurality of IDT electrodes on the piezoelectric layer, and when the wavelength of the surface elastic wave determined by the interval of disposing the plurality of IDT electrodes is λ, the thickness of the piezoelectric layer and the low acoustic velocity layer may be 1λ or less.

Specific matters of other embodiments are included in the detailed description and drawings.

The surface acoustic wave device according to an embodiment of the present invention may provide almost the same performance compared to a surface acoustic wave device including a trap-rich layer, while simplifying the manufacturing process, so that it may have significant advantages in manufacturing cost and throughput.

The effects of the present invention are not limited to the effects mentioned above, and unmentioned other effects will be clearly understood by those skilled in the art from the description of the claims.

### BRIEF DESCRIPTION OF THE DRAWINGS

FIGS. 1 to 3B are views for explaining a surface acoustic wave device according to the prior art.

FIG. 4 is a cross-sectional view showing the configuration of a surface acoustic wave device according to an embodiment of the present invention.

FIG. 5 is a view for explaining the result of EDX analysis conducted on a bonding unit between a support substrate, having a modified substrate surface layer on the surface, and a low acoustic velocity layer in a surface acoustic wave device according to an embodiment of the present invention.

FIG. 6 is a view for comparing the surface roughness of a trap-rich layer formed by ion implantation.

FIG. 7 is a view for explaining the relation between the plasma process time and the thickness of a substrate surface layer modified as an amorphous layer in a surface acoustic wave device according to an embodiment of the present invention.

FIGS. 8 and 9 are graphs for explaining performance of a surface acoustic wave device according to an embodiment of the present invention.

FIG. 10 is a flowchart illustrating a method of manufacturing a surface acoustic wave device according to an embodiment of the present invention.

FIGS. 11 to 13 are views showing intermediate steps for explaining a method of manufacturing a surface acoustic wave device according to an embodiment of the present invention.

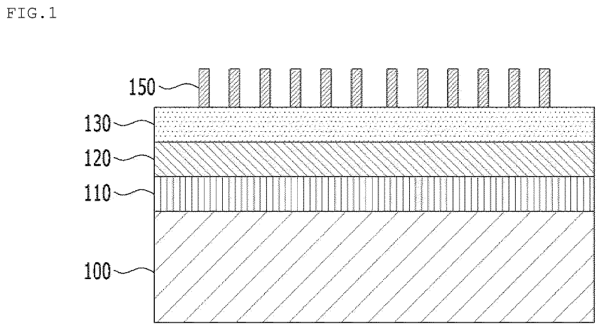

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. These embodiments are provided only to make the disclosure of the present invention complete and to fully inform those skilled in the art of the scope of the present invention, and the present invention is only defined by the scope of the claims. Like reference numerals refer to like elements throughout the specification.

When one component is referred to as being “connected to” or “coupled to” another component, it includes both the cases of being directly connected or coupled to another components and cases of interposing other components in between. On the contrary, when one component is referred to as being “directly connected to” or “directly coupled to” another component, it indicates that no other component is intervening therebetween. “And/or” includes each of the mentioned items and all combinations of one or more of the items.

The terms used in this specification are to describe the embodiments and are not to limit the present invention. In this specification, singular forms also include plural forms unless specifically stated otherwise in the phrases. The terms “comprises” and/or “comprising” used in this specification means that the mentioned components, steps, operations, and/or elements do not exclude the presence or addition of one or more other components, steps, operations and/or elements.

Although first, second, and the like are used to describe various components, these components are of course not limited by these terms. These terms are used only to distinguish one component from the others. Therefore, it goes without saying that a first component mentioned below may also be a second component within the technical spirit of the present invention.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specifically defined.

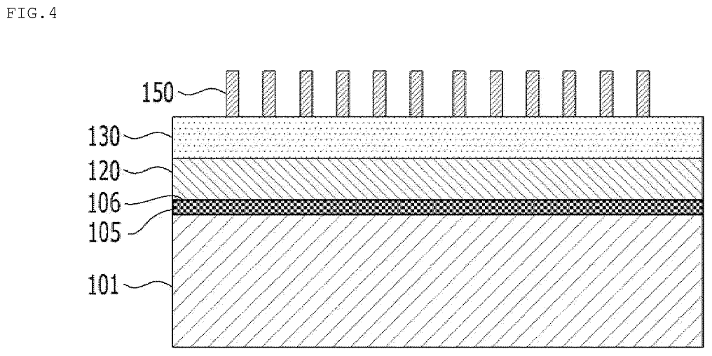

FIG. 4 is a cross-sectional view showing the configuration of a surface acoustic wave device according to an embodiment of the present invention.

Referring to FIG. 4, a surface acoustic wave device according to an embodiment of the present invention may include a support substrate 101, a modified substrate surface layer 105, a low acoustic velocity layer 120, a piezoelectric layer 130, and a plurality of IDT electrodes 150.

The support substrate 101 may include a material in which the acoustic velocity of slow transverse waves is higher than the acoustic velocity of surface acoustic waves propagating in the piezoelectric layer 130, and may be made of any one of materials such as a silicon substrate, silicon carbide, and gallium nitride, but the present invention is not limited thereto. Hereinafter, the support substrate 101 is described as a high-resistivity silicon substrate having a resistivity of 4 kΩ cm or higher.

The low acoustic velocity layer 120 may be made of a material having an acoustic velocity lower than the acoustic velocity of the surface elastic wave of the piezoelectric layer 130, and may include one or more among, for example, silicon oxide (SiO₂), tantalum pentoxide (Ta₂O₅), tellurium dioxide (TeO₂), and the like.

The piezoelectric layer 130 includes a piezoelectric element and may generate elastic waves from signals applied to a plurality of IDT electrodes 150, and may contain materials such as LiTaO₃ (LT), LiNbO₃ (LN), or the like.

A plurality of IDT electrodes 150 may be disposed on the piezoelectric layer 130, and when the wavelength of the surface elastic wave determined by the interval of disposing the plurality of IDT electrodes 150 is λ, the thickness of the piezoelectric layer 130 and the low acoustic velocity layer 120 may be 1λ or less.

The modified substrate surface layer 105 may be formed on the surface of the support substrate 101. The modified substrate surface layer 105 may include, for example, an amorphous layer formed by surface treatment on the support substrate 101 using argon plasma or the like. Accordingly, the modified substrate surface layer 105 may include both a material that forms the support substrate 101 and a material used for plasma surface treatment. Meanwhile, in addition to argon, an inert gas such as He, Ne, Kr, Xe, or the like may be used for plasma treatment of the support substrate 101, and in this case, the modified substrate surface layer 105 may partially include corresponding materials.

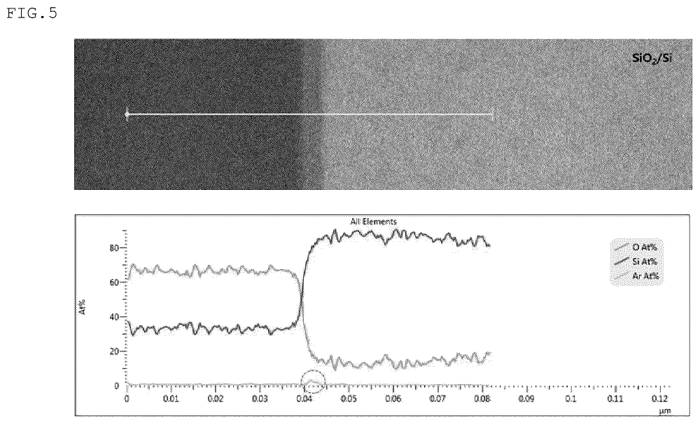

FIG. 5 is a view for explaining the result of Energy Dispersive Spectrometer (EDX) analysis conducted on a bonding unit between a support substrate 101, having a modified substrate surface layer 105 on the surface, and a low acoustic velocity layer 120 in a surface acoustic wave device according to an embodiment of the present invention. For the EDX analysis, a silicon substrate is used for the support substrate 101, silicon oxide is used for the low acoustic velocity layer 120, and the modified substrate surface layer 105 is formed for argon plasma surface treatment.

Referring to FIG. 5, a Transmission Electron Microscope (TEM) image of the bonding unit is shown on the upper part, and a graph showing the result of EDX analysis is shown on the lower part. In the graph, the horizontal axis represents depth, and the vertical axis represents the content ratio of each material.

As shown in the EDX graph, the modified substrate surface layer 105, in which the material of the interface is amorphous silicon, is formed between the low acoustic velocity layer 120 and the support substrate 101, and it can be seen that a small amount of argon is detected inside the modified substrate surface layer 105 formed to have a thickness of 10 nm or lower. Since argon is not detected in the low acoustic velocity layer 120, the argon contained in the modified substrate surface layer 105 is not introduced when the low acoustic velocity layer 120 is deposited.

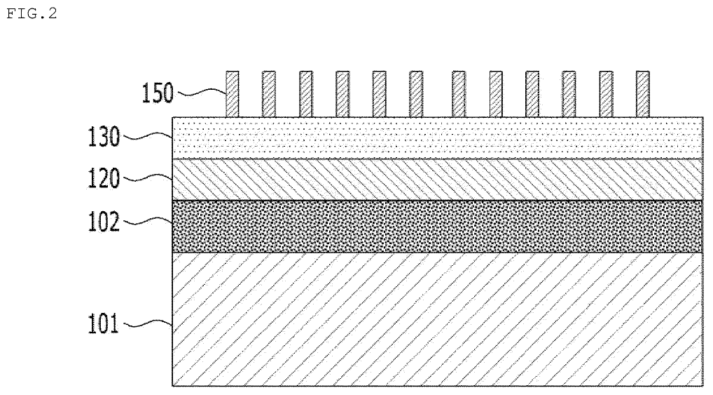

Since the modified substrate surface layer 105 is formed thinly only on the surface of the support substrate 101, the thickness may be much lower than that of the trap-rich layer 102 formed to have a thickness of 400 to 600 nm through the deposition process described above using FIG. 2. The modified substrate surface layer 105 may be formed to have a thickness of 10 nm or lower, and this is a considerably low thickness compared to the trap-rich layer 102 formed to have a thickness of at least 50 nm through the deposition process.

When argon or the like is ion-implanted into the support substrate 101, the surface roughness of the support substrate 101 changes. As the acceleration voltage is increased, the implantation amount is increased, and the implantation angle is optimized to increase the throughput of ion implantation, the surface roughness is increased.

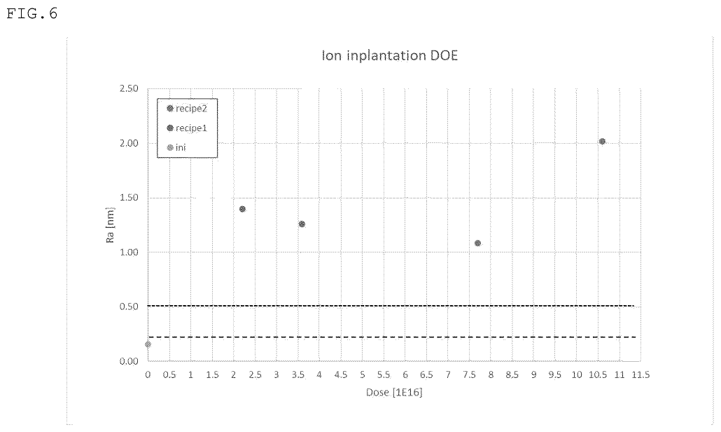

FIG. 6 is a view for comparing the surface roughness of a trap-rich layer formed by ion implantation.

Referring to FIG. 6, the surface roughness Ra before ion implantation is 0.15 nm, but it is observed that the surface roughness Ra increases to be about 1 to 2 nm after ion implantation. In order to bond the support substrate and the piezoelectric layer through wafer bonding, a surface roughness of 0.5 nm or lower is essential, and 0.2 nm or lower is preferable. Therefore, in order to apply wafer bonding to a support substrate having a surface with a roughness as shown in FIG. 6, an additional process is required separately.

In contrast thereto, when the modified substrate surface layer 105 is formed by plasma surface treatment, like the surface acoustic wave device according to an embodiment of the present invention, the effect of increasing the surface roughness described above does not occur, and a surface roughness of 0.2 nm or lower may be obtained easily, which allows wafer bonding to be formed on one side 106 of the modified substrate surface layer 105 bonded to the low acoustic velocity layer 120.

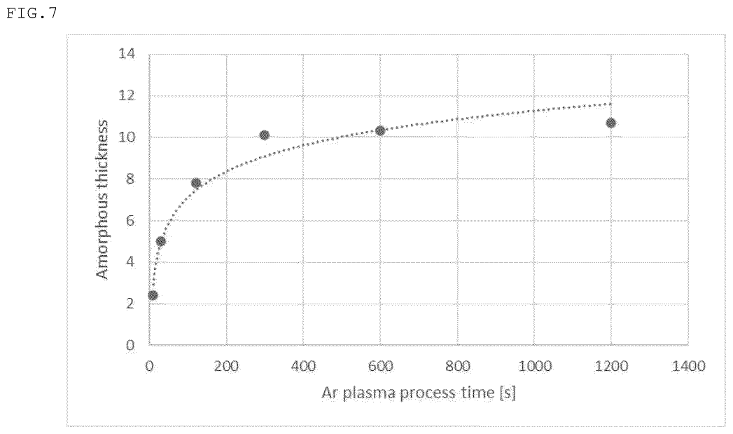

FIG. 7 is a view for explaining the relation between the plasma process time and the thickness of a substrate surface layer 105 modified as an amorphous layer in a surface acoustic wave device according to an embodiment of the present invention.

Referring to FIG. 7, it is observed that when duration of plasma treatment is increased, the thickness of the modified substrate surface layer 105 converges to about 10 nm. When the trap-rich layer is formed by ion implantation or the like described above, a thickness as low as 50 nm to several hundred nanometers may be obtained relatively easily. However, in the case of plasma treatment using argon or the like, it is somewhat difficult to deeply modify the surface of the support substrate 101 through a process that uses much low energy, rather than the ion implantation. Accordingly, the surface acoustic wave device according to an embodiment of the present invention includes a modified substrate surface layer 105 having a thickness as low as about 10 nm while maintaining the change in the surface roughness to be small.

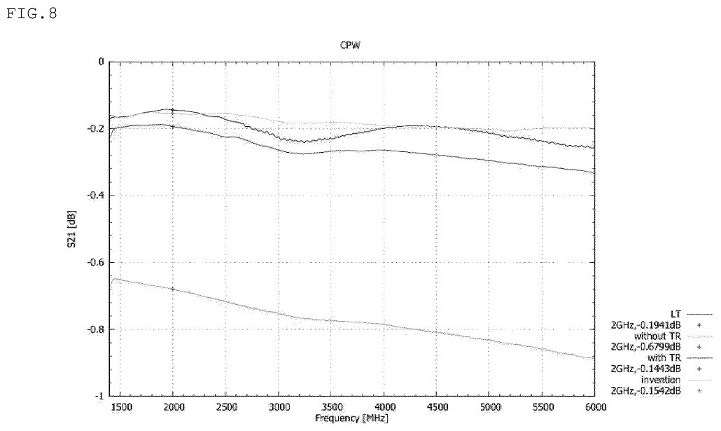

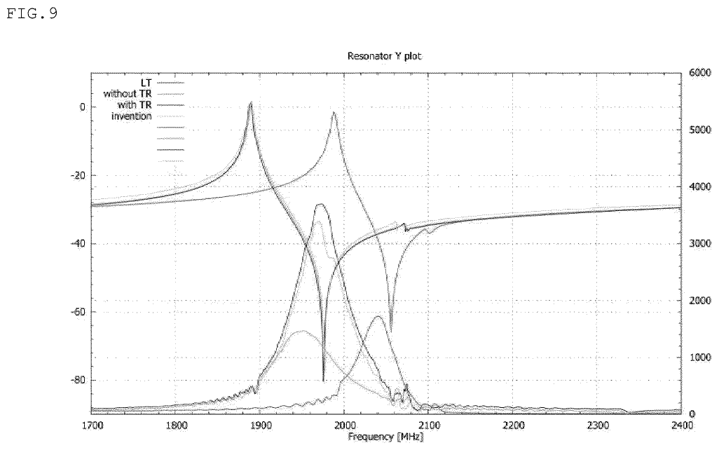

FIGS. 8 and 9 are graphs for explaining performance of a surface acoustic wave device according to an embodiment of the present invention.

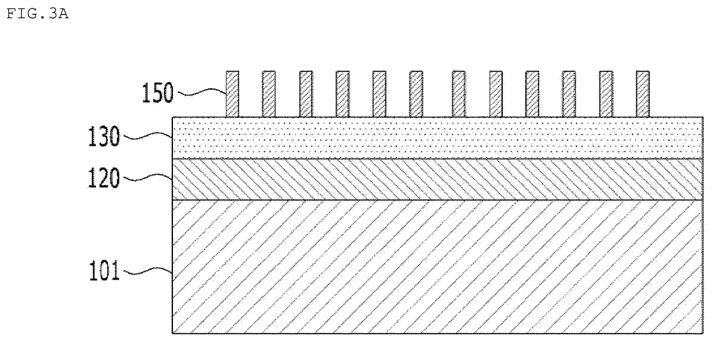

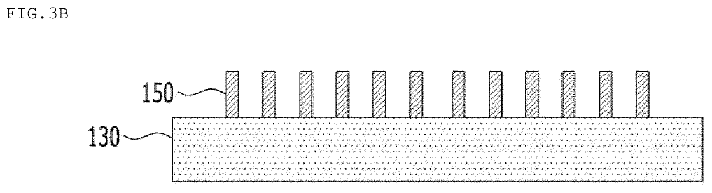

First, referring to FIG. 8, a graph of high-frequency loss measured in the surface acoustic wave device according to an embodiment of the present invention is shown. The yellow graph corresponds to the high-frequency loss measured in the surface acoustic wave device of the present invention shown in FIG. 4, and the blue graph, green graph, and red graph correspond to the high-frequency loss measured in the surface acoustic wave devices shown in FIGS. 2, 3A, and 3B, respectively. A method of measuring insertion loss by patterning a coplanar waveguide (CPW) with aluminum on the surface of a laminating structure is used in each of the cases. The length of the CPW is 2 mm.

First, seeing the high-frequency loss of the device having a three-layer structure of a support substrate, a low acoustic velocity layer, and a piezoelectric layer (FIG. 3A), it shows a change of 0.6 to 0.9 dB in each band, and the high-frequency loss of the device having only a piezoelectric layer (FIG. 3B) shows a change of 0.19 to 0.32 dB.

Meanwhile, a device having a four-layer structure including a trap-rich layer as shown in FIG. 2 has an insertion loss of 0.14 to 0.24 dB in each band, and this is a significant difference considering that the difference of the insertion loss is 0.1 dB in a band-pass surface acoustic wave filter.

Finally, it can be confirmed that the insertion loss measured in the surface acoustic wave device having a structure, in which a modified surface substrate layer is formed as shown in an embodiment of the present invention, is measured to be 0.15 to 0.21 dB, and this shows an insertion loss of a level similar to that of a surface acoustic wave device including a trap-rich layer.

Referring to FIG. 9, graphs of admittance characteristics and Q characteristics measured in the surface acoustic wave device according to an embodiment of the present invention are shown. The yellow graph corresponds to the admittance and Q value measured in the surface acoustic wave device of the present invention shown in FIG. 5, and the blue graph, green graph, and red graph correspond to the admittance and Q value measured in the surface acoustic wave devices shown in FIGS. 2, 3A, and 3B, respectively.

First, the maximum Q values of the device having a three-layer structure of a support substrate, a low acoustic velocity layer, and a piezoelectric layer (FIG. 3A) and the device having only a piezoelectric layer (FIG. 3 are 1600 and 1800, respectively, and compared to the maximum Q value of approximately 3900 of a device having a four-layer structure including a trap-rich layer as shown in FIG. 2, significantly deteriorated performance can be confirmed.

In contrast thereto, the maximum value of the Q value measured in a surface acoustic wave device having a structure in which a modified surface substrate layer is formed as shown in an embodiment of the present invention is approximately 3600, which is almost similar to that of the device of FIG. 2, and the resonance frequency, anti-resonance frequency, and electrostatic capacitance shown in the admittance characteristic are also almost the same as those of the device of FIG. 2.

In summary, the surface acoustic wave device including a modified substrate surface layer according to an embodiment of the present invention may provide almost the same performance compared to a surface acoustic wave device including a trap-rich layer, while simplifying the manufacturing process, so that it may have significant advantages in manufacturing cost and throughput.

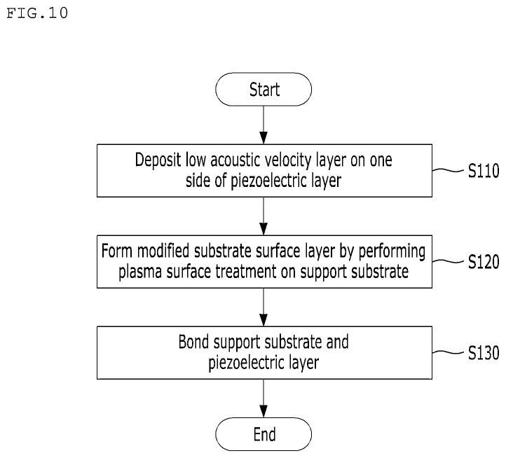

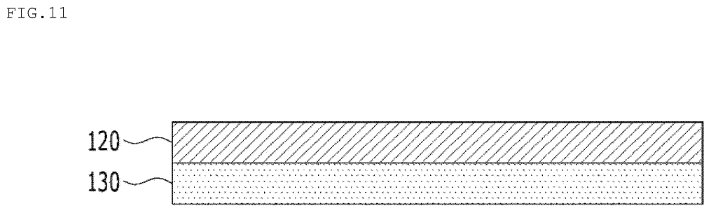

FIG. 10 is a flowchart illustrating a method of manufacturing a surface acoustic wave device according to an embodiment of the present invention, and FIGS. 11 to 13 are views showing intermediate steps for explaining the manufacturing method.

Referring to FIG. 10, a method of manufacturing a surface acoustic wave device according to an embodiment of the present invention may include a step of depositing a low acoustic velocity layer on one side of a piezoelectric layer (S110), a step of forming a modified substrate surface layer by performing plasma surface treatment on a support substrate (S120), and a step of bonding the support substrate and the piezoelectric layer (S130).

Referring to FIG. 11, a step of depositing a low acoustic velocity layer 120 on one side of a piezoelectric layer 130 is performed. The piezoelectric layer 130 may contain materials such as LiTaO₃ (LT), LiNbO₃ (LN), and the like, and the low acoustic velocity layer 120 may be formed by growing a material selected from silicon oxide (SiO₂), tantalum pentoxide (Ta₂O₅), tellurium dioxide (TeO₂), and the like in a method such as thermal oxidation or the like, or by depositing the material in a method such as Chemical Vapor Deposition (CVD), sputtering, or the like. Surface roughness can be reduced as needed by grinding the surface of the low acoustic velocity layer 120 by Chemical Mechanical Polishing (CMP) or the like.

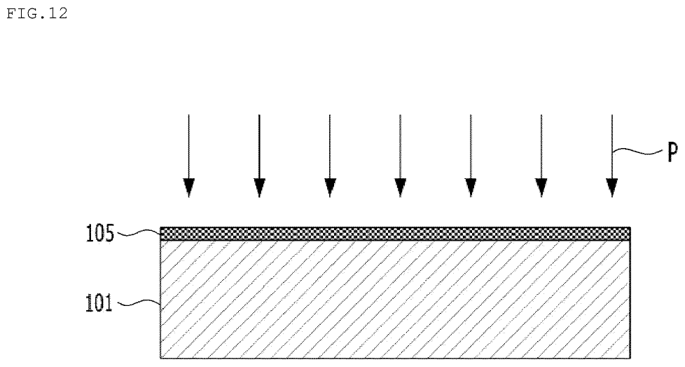

Referring to FIG. 12, a modified substrate surface layer 105 is formed by performing plasma surface treatment on the support substrate 101. The modified substrate surface layer 105 may be formed by modifying the surface of the support substrate 101 into an amorphous layer through argon plasma surface treatment on the support substrate 101 including any one among a silicon substrate, a silicon carbide, and a gallium nitride and having a surface processed like a mirror. At this point, the modified substrate surface layer 105 may be formed to have a thickness of 10 nm or lower, and may include some of materials used in the plasma surface treatment. Prior to surface treatment, a process of removing a natural oxide film formed on the support substrate 101 may be performed.

In some embodiments of the present invention, removal of impurities and reduction of surface roughness on the surface of the support substrate 101 may also be performed by plasma surface treatment that is performed to form the modified substrate surface layer 105.

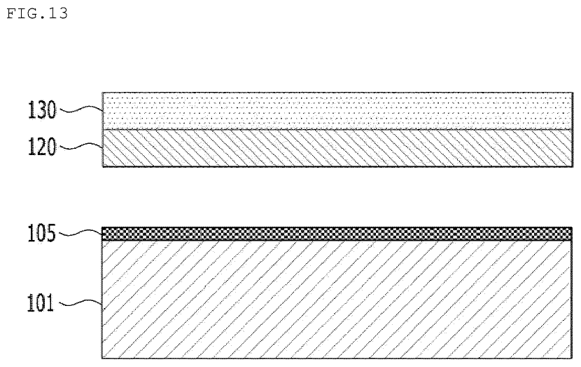

Referring to FIG. 13, the support substrate 101 and the piezoelectric layer 130 are bonded to each other. That is, one side of the support substrate 101, on which the modified substrate surface layer 105 is formed, and one side of the low acoustic velocity layer 120 formed on the piezoelectric layer 130 may be bonded to each other. For the bonding, a hydrophilic treatment process may be performed after activating the bonding surfaces of the two substrates using a mixed gas of N₂/O₂. After the bonding is completed, a process of thinning the piezoelectric layer 130 to a desired thickness may be additionally performed.

In this way, the method of manufacturing a surface acoustic wave device including a modified substrate surface layer according to an embodiment of the present invention does not require a separate deposition process to form a trap-rich layer. In order to guarantee performance by a conventional trap-rich layer, the trap-rich layer needs to be deposited through an LPCVD, PECVD, or sputtering device to have a thickness of about 400 to 1000 nm, and although the trap-rich layer is formed by ion implantation, a thickness of at least 50 nm needs to be formed by an ion implantation device. In comparison thereto, as the method of manufacturing a surface acoustic wave device according to an embodiment of the present invention only requires a process of forming a modified substrate surface layer 105 by performing plasma surface treatment on the surface of the support substrate 101, the manufacturing time and cost required to guarantee the same performance can be reduced.

Although the embodiments of the present invention have been described above with reference to the accompanying drawings, those skilled in the art may understand that the present invention can be implemented in other specific forms without changing the technical spirit or essential features. Therefore, the embodiments described above should be understood in all respects as illustrative and not restrictive.

### DESCRIPTION OF SYMBOLS

100, 101: Support substrate
105: Modified substrate surface layer
110: High acoustic velocity layer
120: Low acoustic velocity layer
130: Piezoelectric layer
150: IDT electrode

What is claimed is:

1. A surface acoustic wave device comprising:
a semiconductor support substrate;
a modified substrate surface layer formed on a surface of the support substrate;
a low acoustic velocity layer formed on one side of the modified substrate surface layer;
a piezoelectric layer formed on the low acoustic velocity layer; and
a plurality of IDT electrodes disposed on the piezoelectric layer, wherein
surface roughness of one side of the modified substrate surface layer is 0.2 nm or lower.

2. The device according to claim 1, wherein the modified substrate surface layer includes an amorphous layer of a material constituting the support substrate, and the surface roughness is roughness of a boundary surface between the support substrate and the low acoustic velocity layer.

3. The device according to claim 2, wherein the modified substrate surface layer contains any one among argon, helium, krypton, and xenon.

4. The device according to claim 2, wherein a thickness of the modified substrate surface layer is 10 nm or lower.

5. The device according to claim 1, wherein when a wavelength of a surface elastic wave determined by an interval of disposing the plurality of IDT electrodes is λ, the thickness of the piezoelectric layer and the low acoustic velocity layer is 1λ or less.

6. The device according to claim 1, wherein the support substrate contains at least any one material among a silicon substrate, a silicon carbide, and a gallium nitride.

7. A method of manufacturing a surface acoustic wave device, the method comprising the steps of:
forming a modified substrate surface layer by performing plasma surface treatment on a surface of a support substrate;
forming a low acoustic velocity layer on a piezoelectric layer; and
bonding the substrate surface layer and a surface of the low acoustic velocity layer.

8. The method according to claim 7, wherein the plasma surface treatment process includes plasma treatment using any one material among argon, helium, krypton, and xenon, and the modified substrate surface layer partially contains any one material among the argon, helium, krypton, and xenon used in the plasma treatment.

9. The method according to claim 7, wherein a thickness of the modified substrate surface layer is 10 nm or lower.

10. The method according to claim 7, wherein the modified substrate surface layer includes an amorphous layer of a material constituting the support substrate.

11. The method according to claim 7, further comprising the step of forming a plurality of IDT electrodes on the piezoelectric layer, wherein when a wavelength of a surface elastic wave determined by an interval of disposing the plurality of IDT electrodes is λ, the thickness of the piezoelectric layer and the low acoustic velocity layer is 1λ or less.

12. The method according to claim 11, wherein the support substrate contains at least any one material among a silicon substrate, a silicon carbide, and a gallium nitride.
